(19) United States
(12) Patent Application Publication
(10) Pub. No.: US 2026/0261233 A1
(43) Pub. Date: Sep. 3, 2026

(54) MULTI-FUNCTIONAL, FOLDABLE, ASYMMETRIC PHOTOVOLTAIC SYSTEM AND METHOD

(71) Applicant: KING ABDULLAH UNIVERSITY OF SCIENCE AND TECHNOLOGY, Thuwal (SA)

(72) Inventors: Michele DE BASTIANI, Thuwal (SA); Niclas HEESCHER, Saerbeck (DE); Michael Filipe SALVADOR, Thuwal (SA); Emmanuel P. VAN KERSCHAVER, Mountain View, CA (US)

(21) Appl. No.: 19/489,457

(22) PCT Filed: Jun. 12, 2024
(86) PCT No.: PCT/IB2024/055752

§ 371 Date: Dec. 2, 2025

Related U.S. Application Data
(60) Provisional application No. 63/472,439, filed on Jun. 12, 2023.

(51) Int. Cl. H02S 30/20; H02S 40/34; H02S 40/36

(52) U.S. Cl. CPC H02S 30/20; H02S 40/34; H02S 40/36

(57) ABSTRACT

A retractable and modular photovoltaic (PV) system for transforming solar energy into electrical energy includes a first asymmetric PV module including (i) a first part free of PV cells, and (ii) a second part including first plural PV cells for generating the electrical energy; a first end junction box electrically connected to a first end of the first plural PV cells; and a second end junction box electrically connected to a second end of the first plural PV cells. The first asymmetric PV module is made of a bendable material so that the first part bends relative to the second part along a boundary when the first asymmetric PV module is retracted.

### CROSS-REFERENCE TO RELATED APPLICATIONS

This application claims priority to U.S. Provisional Patent Application No. 63/472,439, filed on Jun. 12, 2023, entitled “MULTI-FUNCTIONAL, FOLDABLE PHOTOVOLTAIC SYSTEM AND METHOD,” the disclosure of which is incorporated herein by reference in its entirety.

### BACKGROUND

### Technical Field

Embodiments of the subject matter disclosed herein generally relate to a photovoltaic system that uses solar radiation for generating energy, and more specifically, to techniques and processes for asymmetrically arranging solar cells in the photovoltaic system and providing reliable connections between the various modules that form the photovoltaic system.

### Discussion of the Background

Photovoltaic modules 110 (discovered by the present inventors, see) [2]), as illustrated in FIG. 1, include plural photovoltaic (PV) cells 112 (for example, silicon based solar cells) electrically connected to each other in series and supported by a common substrate 114 (see [1]). The figure shows each cell 112 being electrically connected to adjacent cells through intra-module electrical connections 116. In the present embodiment, plural modules 110 are mechanically and electrically connected to each other for obtaining a foldable photovoltaic system 100. The figure also shows adjacent modules being electrically connected through inter-module electrical connections 118. Edges of the modules 110 are mechanically attached to each other either by sharing the same substrate 114 or by using dedicated hinges or connection mechanisms 120. Two end ports 122 provided at the first and last modules provide the electrical power generated by all the cells 112. All the cells 112 of all the modules 110 are electrically connected in series to each other. Thus, the entire PV system 100 generates a single current having a value dictated by the cell generating the smallest current.

Foldable solar systems as the PV system 100 find useful applications in agriculture applications (see [2]), building-integrated photovoltaics, vehicle-integrated photovoltaics, and portable electronics. In agriculture applications, the foldable modules could be designed with light transmission technologies (see [3]) to optimize the amount of light transmitted to the plants. For this reason, the modules 110 are designed with large gaps G between the PV cells 112, as illustrated in FIG. 1, and transparent front and back sheets 124 are used to sandwich the cells to allow the incoming light to pass the system and reach the plants covered by the modules. Foldable solar modules are usually expanded when in operation (see FIG. 2) and retracted when not in operation (see FIG. 3). These figures also schematically show an actuator 210, which is connected to one or more modules 110 and help the system 100 to fold and unfold.

When PV system 100 is fully expanded, as shown in FIG. 2, the modules 110 are often making a non-zero angle “a” with a horizontal plane 220, i.e., the combined surface of the modules 110 is non-flat due to mechanical tension, gravity, the presence of a supporting structure, and/or other factors.

This situation is best illustrated in FIG. 2, which shows only two incoming light rays 222 and 224 impinging on two adjacent modules 110. The figure shows the normal N to the surface of the modules, where the light enters the cells 112-1 and 112-2, and the angles a1 and a2 between the normal N and the rays 222 and 224, respectively. It is noted that angle a1 is much smaller than angle a2. This means that more light impinges cell 112-1 than cell 112-2. This is problematic for the traditional PV systems because less incident light means less generated current. As discussed above, for plural cells electrically connected in series, the total output current is dictated by the cell that generates the least amount of current. In other words, although cell 112-2 (and there are many of these cells in the system 100) generates a current higher than cell 112-1 (which has the unfavorable orientation), the total output current is limited by the current generated by cell 112-1. This situation severely limits the overall performance of the PV system 100.

Moreover, foldable electrical interconnections integrated or not at hinges or connection mechanisms 120 are prone to failure due to mechanical stress. Flat ribbons embedded in the module's design are currently used to secure hundreds-to-thousands cycles of extension and retraction. However, for the long-term operation, the failure of the flat ribbons represents a major threat to the reliability of foldable solar modules.

In addition, partial shading from the surrounding structures and partial opening of the systems may cause severe reduction in the performance of the PV system 100. Therefore, there is a need for a new system and/or method to mitigate the problems and/or risks noted above.

### SUMMARY

According to an embodiment, there is a retractable and modular photovoltaic (PV) system for transforming solar energy into electrical energy, and the PV system includes a first asymmetric PV module including (i) a first part free of PV cells, and (ii) a second part including first plural PV cells for generating the electrical energy; a first end junction box electrically connected to a first end of the first plural PV cells; and a second end junction box electrically connected to a second end of the first plural PV cells. First asymmetric PV module is made of a bendable material so that the first part (410A) bends relative to the second part along a boundary when the first asymmetric PV module is retracted.

According to another embodiment, there is a retractable and modular photovoltaic (PV) system for transforming solar energy into electrical energy. The PV system includes plural asymmetric PV modules each including (i) a first part free of PV cells, and (ii) a second part including plural PV cells for generating the electrical energy, a first end junction box electrically connected to a first end of a string of all plural PV cells, and a second end junction box electrically connected to a second end of the string of all the first plural PV cells. Each asymmetric PV module is made of a bendable material so that the first part bends relative to the second part along a boundary when the plural asymmetric PV modules are retracted.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 illustrates a traditional foldable PV system in which all the PV cells of all the modules are serially connected to form a single string;

FIG. 2 illustrates the light incidence on the PV cells of the PV system of FIG. 1;

FIG. 3 illustrates the PV system of FIG. 1 being folded;

FIG. 4A illustrates a foldable PV system having PV cells asymmetrically distributed on two parts of each module;

FIG. 4B illustrates a traditional PV system that has cells symmetrically distributed on each part of the PV modules;

FIG. 5 illustrates a connecting mechanism between PV modules of the PV system of FIG. 4A;

FIG. 6 illustrates the predicted power outputs over a day for a traditional PV system arranged north-south and east-west, and for the PV system of FIG. 4A;

FIG. 7A illustrates the high current generated by the PV system of FIG. 4A and FIG. 7B illustrates the mixture of high and low currents generated by the PV system of FIG. 1;

FIG. 8A illustrates a first electrical configuration of the PV system of FIG. 4A and FIG. 8B illustrates a second electrical configuration of the PV system of FIG. 4A;

FIG. 9A illustrates the use of two different clamps for attaching a connecting cable to two adjacent PV modules and FIG. 9B illustrates in more detail one of the two clamps;

FIG. 10 illustrates another electrical configuration of the PV system of FIG. 4A so that sections of pairs of modules that are in shade, are electrically switched on and off;

FIG. 11 illustrates yet another electrical configuration of the PV system of FIG. 4A so that one or more sections of a given module that are in shade, are electrically switched on and off;

FIG. 12 illustrates a modified electrical configuration of the PV system of FIG. 1;

FIG. 13 illustrates the PV system of FIG. 1 or of FIG. 4A being vertically provided with plural limiters; and

FIG. 14 illustrates various elements or materials added to the first part of the PV module for added functionality.

### DETAILED DESCRIPTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a PV system having the PV cells distributed asymmetrically on corresponding modules.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

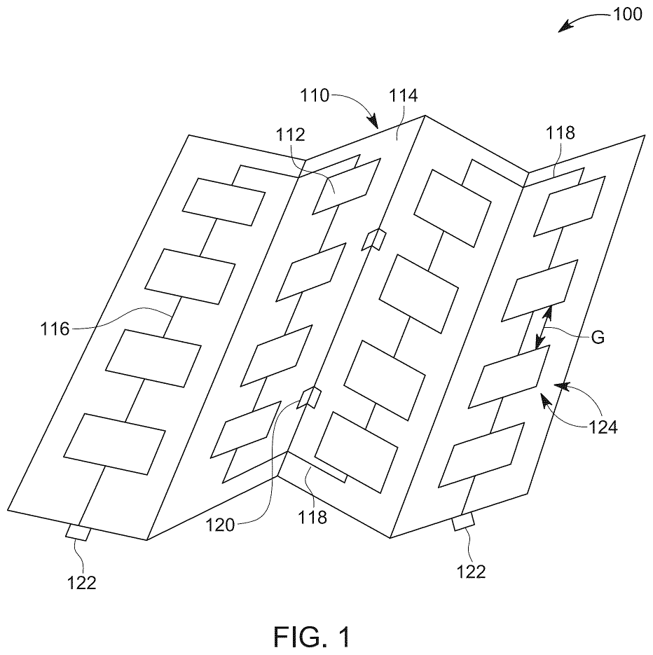

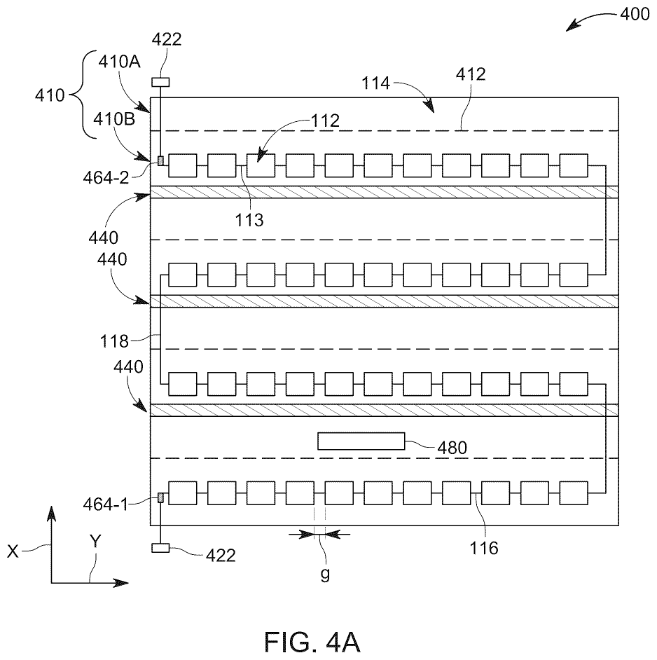

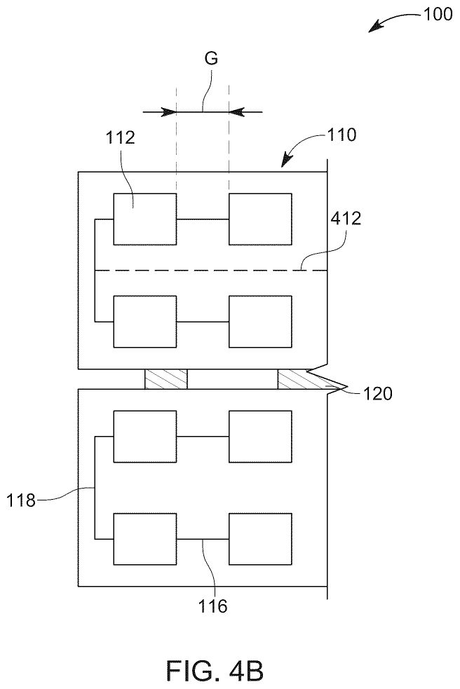

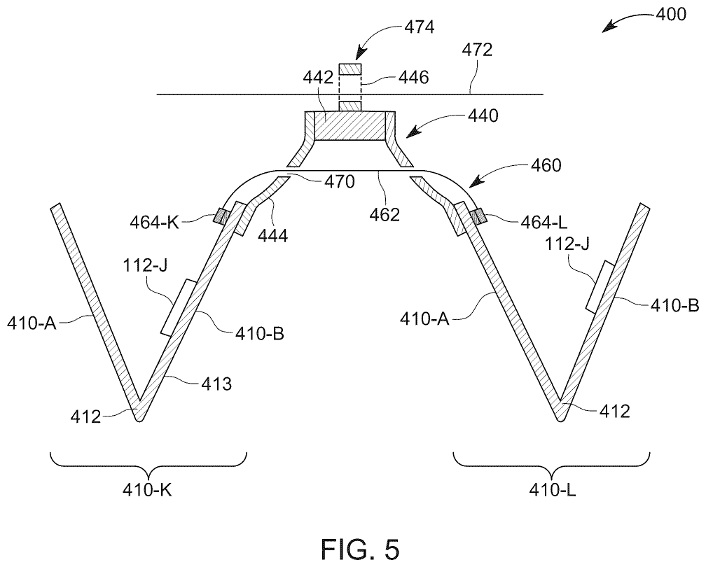

According to an embodiment, as illustrated in FIG. 4A, a PV system 400, which overcomes one or more deficiencies of the PV system 100 shown in FIG. 1, includes plural asymmetric PV modules 410. Two adjoint asymmetric PV modules 410 are mechanically connected to each other by a connecting mechanism 440, which is discussed later and shown in more detail in FIG. 5. Each asymmetric PV module 410 has a first (empty) part 410A that includes no cells 112, and a second (loaded) part 410B that includes all the cells 112 of that module. The first part may include a specific material or sensor 480, different from a cell 112. In one application, a surface area of the first part 410A is substantially equal to a surface area of the second part 410B. In another application, the two surface areas are not equal, but each is at least 35% of the entire surface areas of the entire module 410. The two surface areas are delimited by a boundary 412. When module 410 is not folded, boundary 412 is practically not visible as this boundary is not made of a specific material. However, when module 410 is folded in two, as shown in FIG. 5, the boundary 412 is visible, i.e., it is the bent region between the two parts 410A and 410B. In this regard, when the PV system 400 is fully folded, each module 410 is bended at the boundary 412. Thus, each module 410 is made of bendable materials to allow the two parts 410A and 410B to fold onto each other. Further, the connecting mechanism 440 may be attached to a support member, as shown in FIG. 5, and may be actuated to unfold the modules 410.

Returning to FIG. 4A, it is noted that the string of cells 112 (occupying the loaded parts 410B) for each module 410 alternates with spaces lacking any PV cell 112 (corresponding to the empty parts 410A), which are fully or partially transparent to light. Any type of PV cell 112 may be used in the PV system 400. Because there are no PV cells in the empty parts 410A, there is no need to have any electrical cable extending from the loaded parts 410B to the empty parts 410A. This means that there are no electrical wires passing through the boundaries 412, where the bending tension is highest. This also means that there are no electrical failure points in the boundaries 412, which solves one of the problems experienced by the traditional modules. For comparison, FIG. 4B shows the existing PV system 100 that includes series of cells 112 on both parts of the module 110, which means that a connecting cable 118 experiences the bending tension when the module 110 is bent at boundary 412.

In one embodiment, a distance g between adjacent PV cells 112 along the length (axis Y in the figure, axis X shows the folding direction) of the module 410 is selected to be much smaller than a corresponding distance G of the traditional module 110 so that a larger number of cells 112 is distributed on the second part 410B. In this regard, in one embodiment, the cells are so closely packed together that the part 410B may be fully opaque, potentially creating a stripped shade structure on the ground. However, because the part first part 410A can be made of highly light scattering material, there will no pattern on the ground in this embodiment. The cells 112 of the PV system 400 may be connected in series or in parallel or in mixed arrangements, as discussed further in more detail. In one embodiment, the entire PV system 400 has two end ports 422, connected to end junction boxes 464-1 and 464-2, as illustrated in FIG. 4A. An end junction box is considered herein to be a junction box where the current or voltage is harvested from the entire PV system 400. As discussed later, additional junction boxes (inner junction boxes) may be used in the PV system to connect together groups or sub-groups of cells, but these inner junction boxes are placed between sub-groups of PV cells or between PV modules, i.e., they are not end junction boxes.

In one embodiment, the total number of cells 112 on module 110 is substantially equal to the total number of cells 112 on module 410 for the same surface area of the two modules. Because of the asymmetric arrangement of the cells 112 over the modules 410, the first part 410A may be fully transparent to light (depending on the materials chosen for this part) while the second part 410B may be substantially opaque to the light because of the non-transparent nature of the PV cells. Thus, the light pattern behind such modules appears as a Zebra, and for this reason, this configuration is called herein a Zebra configuration. In this way, the PV system 400 can secure light transmission to the plants in the range of 40%-100% by appropriate design, which is an advantage of the Zebra configuration. Due to this configuration, the current output of the string of cells is optimized, without limitations due to the different angles and reflection losses typical of conventional designs. The voltage output (at end ports 422) of the panel (which is the sum of the voltage of each cell) is preserved by a higher number of cells per string, because the gap g between the cells 112 was reduced to almost zero in this embodiment.

FIG. 5 illustrates one possible implementation of the folding mechanism 440. Only two PV modules 410-k and 410-l, with k and l being positive integers, and a single connecting mechanism 440 are shown, for simplicity. Note that the PV modules are illustrated in FIG. 5 as being shaped as rectangles, but other shapes may be used for them. Each PV module 410-k and 410-l includes plural PV cells 112-J (where J is an integer equal to or larger than one), and the PV cells are electrically connected to each other to form a single string, as previously discussed with regard to FIG. 4A. PV parts 410-A and 410-B fold along a common boundary 412, formed of a material 413 that encapsulates the PV cells, while PV modules 410-k and 410-l are connected to each other, mechanically, by the connecting mechanism 440, and electrically, by an electrical connection mechanism 460. The same arrangement may repeat for other PV modules in the PV system 400. The electrical connection mechanism 460 includes an electrical cable 462 (highly flexible) configured to connect with its ends to corresponding electrical inner junction boxes 464-k and 464-l, which are attached to the PV modules. The inner electrical junction boxes 464-k and 465-l may be configured with receiving holes for receiving the ends of the cable 462. The inner electrical junction boxes are attached to the PV modules, for example, they are glued.

In this embodiment, the electrical cable 462 is configured to pass through corresponding holes 470 made in a material layer 444, which mechanically connects the PV modules to a bracket 442. The bracket 442, which can be made of plastic, composite, or metal, is a central point for hanging the PV modules to a hanging wire 472. Plural hanging wires may be used to support all the PV modules 410 of the PV system 400. In this embodiment, clips 474 (only one shown for simplicity) are attached to the bracket 442, and have corresponding holes 446, which are configured to receive the hanging wire 472. Thus, each clip 474 is configured to slide along a corresponding hanging wire 472. FIG. 5 further shows the connecting mechanism 440 including the bracket 442, and two fabric layers 444, each layer attached with one end to the bracket and with the other end to a corresponding PV module by any means, i.e., screws, glue, profiles, etc. One skilled in the art would understand that other connecting mechanisms may be used for attaching the PV modules to each other and for suspending them from the hanging wires 472. While FIG. 5 shows the hanging wires 472 and the extended PV system 400 extending horizontally, it is also possible that the wires and PV system extend vertically, as discussed later.

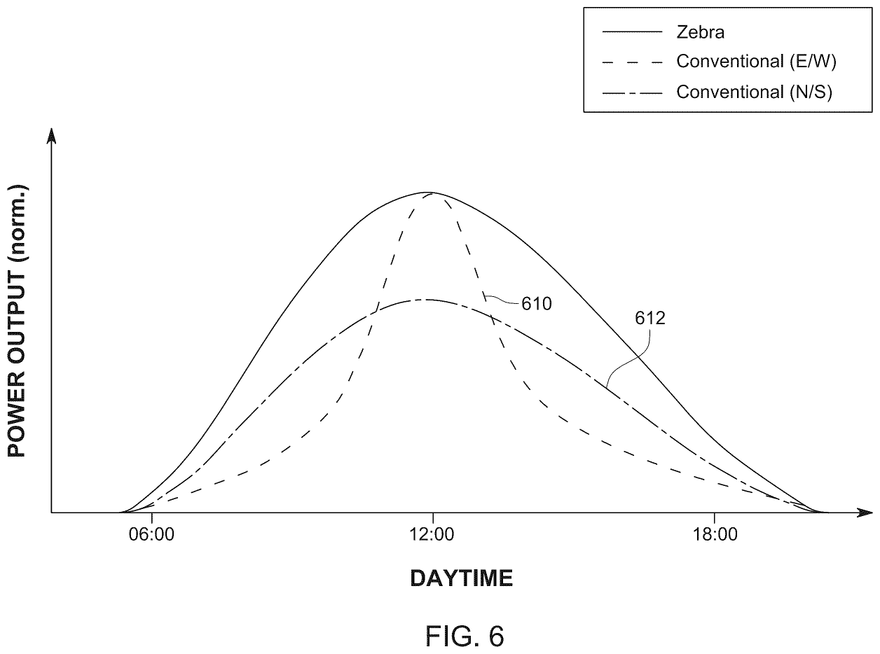

The above discussed configurations minimize the losses caused by a non-optimal orientation of the solar modules 410 with respect to the incoming light. The reflected light escaping from the surface of the modules has the same angle as the incoming light with respect to the perpendicular direction of the panel surface. Thus, the bigger the incident angle, the bigger the reflection loss. This means that the energy loss will be more significative in the morning and in the afternoon if the extension (opening) of the module is oriented east-west (see curve 610 in FIG. 6), and less impacted over the day if the extension of the module is oriented north-south (see curve 612 in FIG. 6). Thus, the power output may experience a sharp rise around mid-day in the case of the east-west orientation and is expected to be flatter in the case of the east-west orientation.

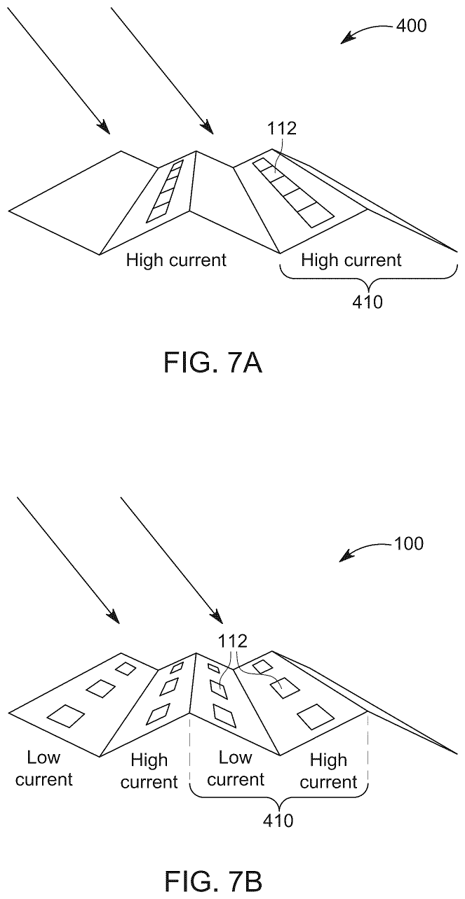

The working mechanism of the PV system 400 is based on the fact that each module “sees” the same irradiation, over the whole length of the panel. Conversely, with the conventional design, if the combined surface of all modules is not perfectly flat, the string of cells may see different irradiation levels, according to the Sun's position. This results in a non-uniform current generation that limits the power output of the entire system. FIG. 7A visualizes the current generated by the string of cells in the PV system 400 (note that all cells have the same inclination to the incoming light rays) and FIG. 7B visualizes the same for a conventional PV system 100 (E/W) for a morning condition (with various cells making different angles with the incoming light rays).

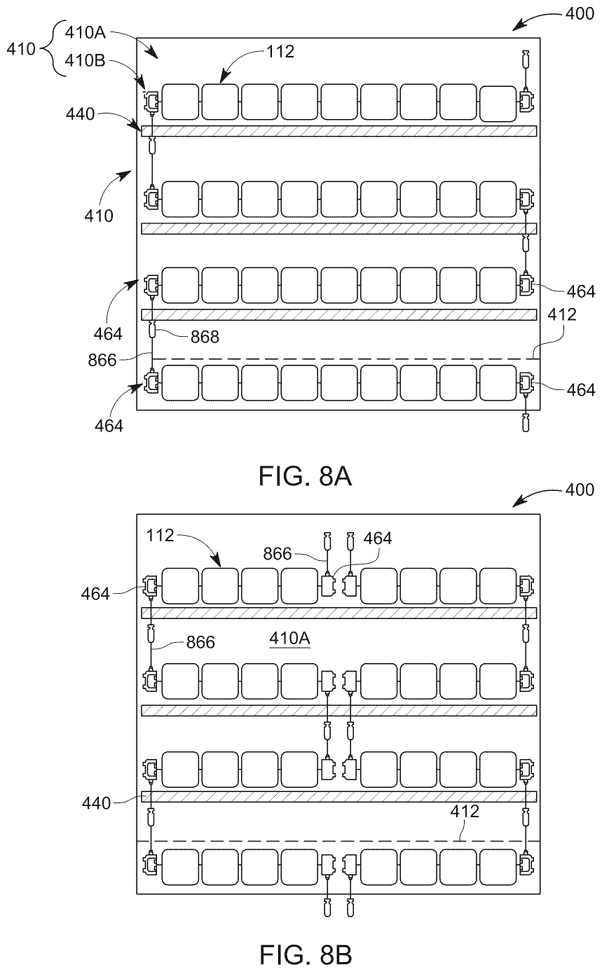

The electrical connections between the strings of cells (each module includes at least one string of cells) in the PV system 400 may be modified when compared to the traditional PV system 100 for preventing cable failure due to bending and/or for increasing a current generated by each module. FIGS. 8A and 8B illustrate two electrical connection configurations between modules 410 for the PV system 400. FIG. 8A shows each module 410 having a single string of cells. Each string of cells 112 for a given module 410 is being sandwiched between corresponding inner junction boxes 464. Each inner junction box from one module is electrically connected to another inner junction box of another module by a connecting cable 866. The connecting cable 866 may be just a wire or may include a male/female connection 868 so that the cable 866 may be separated into two portions to disconnect one module from the next module. FIG. 8B shows each module 410 the string of cells 112 being split into two (or more) groups, and each group is sandwiched by corresponding inner junction boxes 464. The two (or more) groups may include the same or different number of cells. For this configuration, each group of cells from a module is electrically connected with a corresponding group of cells from an adjacent module, in essence forming two (or more) voltage or current sources for the existing cells of the PV system 400. The two voltage or current sources are then connected in series or parallel (not shown) for generating an output at end ports 422.

These configurations solve the limitations of the electrical interconnection along the folding interface in the traditional PV systems. In the Zebra configurations, the foldable system is composed of individual strings/modules, electrically independent, that are interconnected using highly flexible cables 866 (rather than flat ribbon that is prone to breakage). The cables are secured with standard junction boxes 464 in each string/module, certified for PV applications. The two configurations illustrated in FIGS. 8A and 8B allow for a more versatile design of the overall photovoltaic system and easier installation

An advantage of integrating the cabling and junction boxes is the drastic reduction of interconnection failure (breakage of flat copper ribbon) at the folding line (boundary 412) of each module. Conventional interconnects (see FIG. 1) are made of thin and flat copper ribbon that is folded along the folding line. However, mechanical stress may damage the copper ribbon, resulting in failure modes of the panel (i.e., loss of conductivity, isolation of the cell string, heat dissipation/hot spots, etc.). These problems are avoided by the arrangements illustrated in FIGS. 8A and 8B as the connecting cables 866 are minimally bending with the folding of the modules 410.

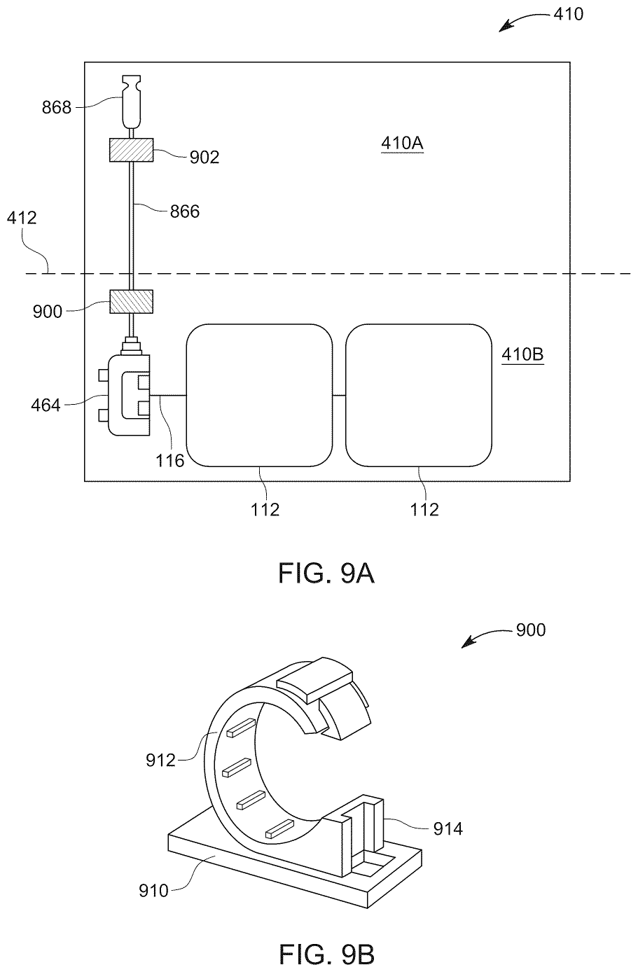

In this regard, the arrangement of the connecting cable 866 relative to a PV module 410 is shown in FIG. 9A. Cable 866 has a first end attached to an inner junction box 464, which is attached to the second part 410B of the module 410. Next to the inner junction box, still on the second part 410B, there is a clamp or cable clip 900, which is illustrated in FIG. 9B in more detail. Clamp 900 is fixedly attached to the second portion 410B, for example, by glue. Other attachment methods may be used to secure the clamp to the surface of the module. The clamp is shown in FIG. 9B having a base 910, which is fixed to a surface of the module 410, and an opening part 912, which is configured to engage a lock 914 for fixing the cable 866 relative to the clamp 900. This means that an interior diameter of the opening part 912 and the base 900, when the opening part is locked by the lock 914, is equal to or slightly less than an exterior diameter of the cable 866, so that the cable 866 does not slide relative to the clamp 900. Clamp 900 may be placed immediately adjacent to the inner junction box 464 and/or boundary 412. Clamp 900 is expected to receive most of the mechanical tension during the folding of the module 410.

A second clamp 902 (similar to clamp 900) is attached to the first part 410A of the PV module 410 to guide the cable 866. This means that an internal diameter of the opening part 912 and base 910 of the second clamp is larger than an external diameter of the cable 866 so that the cable slides relative to the second clamp 902. In one embodiment, the first clamp is called a fixing clamp, and the second clamp is called a guiding clamp. While the structure of these two clamps may be identical, the difference between them is the size of the inner diameter of the opening part 912. As also discussed above, cable 866 (corresponding to cable 462) may go through the fabric layer 444, shown in FIG. 5. The larger diameter of the second clamp 902 allows the cable 866 to slide and adjust during retraction and extension of the modules 410. The second clamp acts as a guide to avoid the folding of the cable within the module, which may prevent cracking of solar cells 112. The clamps may be secured to the module with the same process used for placing the junction boxes (for example, using adhesive or silicone).

The interconnection discussed above allows for the insertion of bypass (BP) diodes to minimize losses under partial shading. In this disclosure, a bypass diode is understood to be a diode that redirects current when a negative voltage (called a “reverse bias”) is detected. When solar cells (or strings of cells, or modules) are connected in series, the current is limited by the lowest current generated by a cell. Therefore, if the PV system is partially shaded, for example, due to adjacent structures, the performance of the system is significantly compromised. To avoid this problem, two configurations of the PV system 400 are disclosed next, that use BP diodes that minimize the losses induced by partial shading.

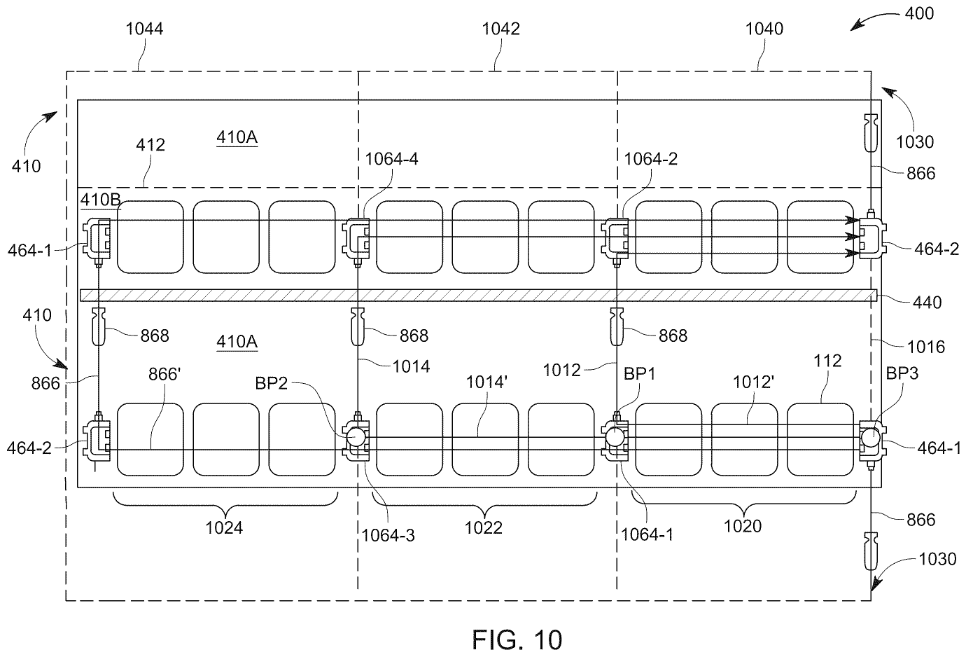

The first configuration is illustrated in FIG. 10 and uses additional inner junction boxes 1064-1 to 1064-4 (two per module in this embodiment, but more or less are possible) to divide the string of cells 112 into each module 410 into sub-sections 1020 to 1024 (more than three sub-sections may be employed). Each sub-section is connected in parallel to the end junction boxes 464-1 and 464-2 (in the right hand end of the figure) of the two modules 410 shown in the figure. Note that the two end junction boxes 464-1 and 464-2 in the right hand side of the figure connect to other cells of other modules, thus forming a string 1030 of cells. Reference is made to the string 1030 in this embodiment. Each sub-section is sandwiched between two inner junction boxes. Each of the additional inner junction boxes 1064-1 and 1064-3 of each second module 410 includes one BP diode (shown in the figure as BP1 and BP2) that can isolate the corresponding section under partial shading, from the rest of the module. The bypass diodes could be in-laminated by using a flat ribbon that would be soldered to the electrical connections between the cells or they can be integrated in the cable between connectors or in the junction boxes, as illustrated in the figure. Note that the next PV module 410 includes the additional inner junction boxes 1064-2 and 1064-4, but not the BP diodes. In other words, the BP diodes are distributed on alternate modules. The BP diode is placed inside the junction box or inside the cable. The junction box may be applied perpendicular to the string ribbon, using a conductive tab (not shown) to secure the electrical connection.

With this arrangement, the PV system 400 is configured to automatically remove one or more sections of PV cells from adjacent modules when in the shade, as now discussed. Suppose that due to an adjacent structure, e.g., a tree or a building, sections 1042 and 1044 of the two PV modules 410 shown in FIG. 10 are not directly exposed to light. This means that, for a traditional system, the cells 112 in these sections will produce less current than the cells 112 in section 1040, which are fully exposed to solar light. As discussed above, the cell producing the least amount of current controls the output of the entire PV system, i.e., the cells in the shade in sections 1042 and 1044 dictate the current output of the entire system. With the BP diodes and additional inner junction boxes discussed above, the BP1 diode determines a negative voltage due to the less current produced by section 1042 relative to section 1040. Thus, BP 1 diode shuts off the cells in sections 1042 and 1044 and redirects the current from the cells 112 in section 1040 along cable 1012 and route 1012′ instead of the traditional cable 866 and route 866′. The term “route” is used in this embodiment for showing in FIG. 10 a path of the current through various cells 112, but the route does not imply that new cables are provided between adjacent cells 112 in the same module 410. Only cables 1012 and 1014 are added in this figure when compared to the configuration 400 shown in FIG. 4A.

In a variation of this embodiment, if only section 1044 is in the shadow, then BP1 diode does not redirect the current, i.e., no current moves along cable 1012. However, because there is now a negative voltage produced by the cells 112 in section 1044, the BP2 diode senses the negative current and redirects the current from cells 112 (of sections 1040 and 1042) along cable 1014 and route 1014′ instead of the traditional cable 866 and route 866′.

Thus, for the configuration illustrated in FIG. 10, the sections in the shadow are practically removed from the current generation, so that only the cells producing the maximum current contribute to the current generation. The switching on and off of the various regions 1040 to 1044 is achieved automatically, by the BP diodes, when a negative voltage is produced by a sub-section in the shadow. While FIG. 10 shows the PV modules 410 being divided into three zones, one skilled in the art would understand that any number of zones may be selected. One skilled in the art will understand that instead of the BP diodes, other electronic devices may be used for switching on and off the various section, for example, a global controller, plural sensor distributed in the various sections, and electronic switches.

In one variation of this embodiment, a third BP3 diode may be added to the end junction box 464-1 in the left hand side of the figure, for removing the entire PV modules shown in the figure, from the string 1030 of cells 112, if the entire modules are in the shade. For this situation, an additional cable 1016 (similar to 866) is added between the junction boxes 464-1 and 464-2 on the left hand side of the figure, to bypass both PV modules. In another modification of this embodiment, no junction box is used. Instead of the junction boxes, a ribbon with an in-laminated diode that extends across the module and connects to the adjacent string of cell may be used.

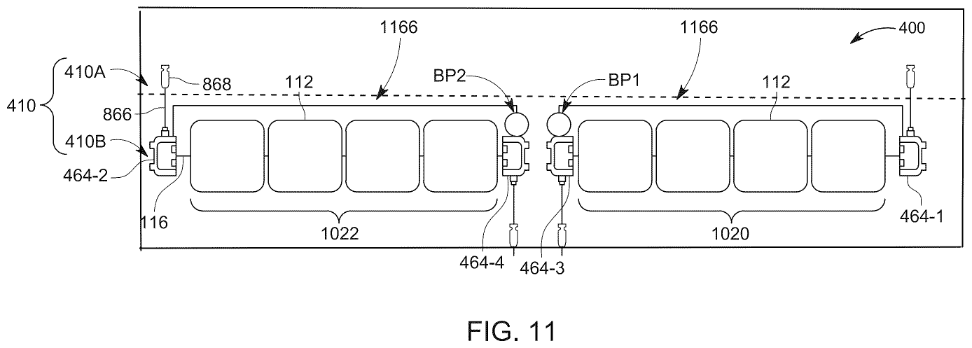

FIG. 11 illustrates a different configuration for the PV system 400. In this embodiment, the cells 112 of the PV module 410 are split into two or more sub-groups 1020 and 1022 (only two are shown for simplicity, but more than two may be used) and each sub-group is electrically sandwiched between corresponding inner junction boxes, e.g., sub-group 1020 is sandwiched between inner junction boxes 464-1 and 464-3, and sub-group 1022 is sandwiched between inner junction boxes 464-2 and 464-4. Junction boxes 464-3 and 464-4 are located next to each other on the second part 410B and include corresponding BP diodes BP1 and BP2. Additional connecting cables 1166 are added, extending along each PV module 410, for connecting the junction boxes (464-1 to 464-3 and 464-2 to 464-4) of each sub-group, as illustrated in the figure. In this way, if the cells in one of the sub-groups are in the shade, the corresponding BP diode receives a negative voltage, which makes the current bypass the cells in the shadow and instead the current flows along the additional connecting cable 1166. In other words, suppose that sub-group 1022 is in the shadow. BP 2 diode receives a negative voltage from the cells of this sub-group and switch the current passing through the cells 112 to the connecting cable 1166 (left hand side of the figure), thus bypassing the cells in the shadow. In other words, the current from other modules enters junction box 464-4, and follow connecting cable 1166 to junction box 464-2, entirely bypassing the cells 112 of the sub-group 1022. In this way, each sub-group of a PV module 410 may be independently electrically isolated from another sub-group of the same module. This embodiment is different from the one illustrated in FIG. 10 because the sub-groups of cells from additional PV modules are simultaneously switched on and off in FIG. 10 while in the embodiment of FIG. 11, sub-groups of a single PV module may be independently switched on and off relative to sub-groups of the same module.

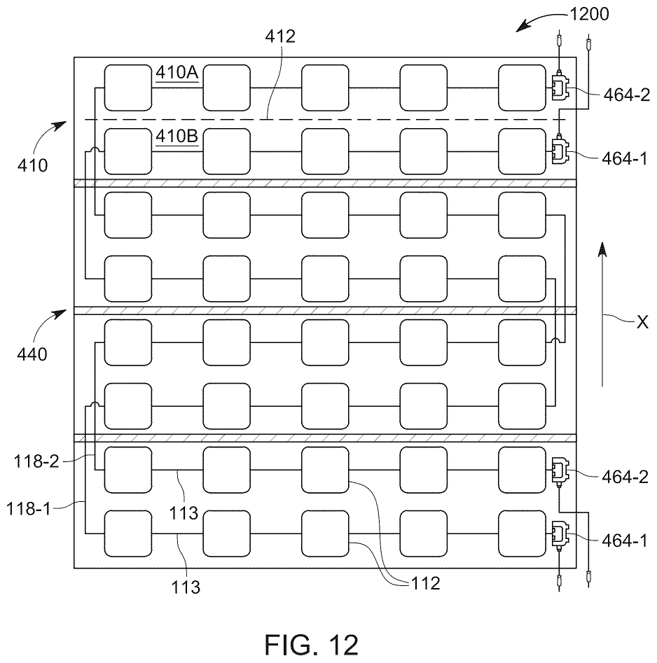

In one embodiment, as illustrated in FIG. 12, a PV system 1200 is electrically configured to provide two current or voltage sources, one between end junction boxes 464-1 and the other one between end junction boxes 464-2. For this embodiment, all the cells 112 from the first regions 410A of all the modules 410 are connected in series between end junction boxes 464-2 and all the cells 112 from the second regions 410B of all the modules 410 are connected in series between end junction boxes 464-1. Thus, if the incoming solar light is more favorable for the first parts, then these parts generate a higher current then the second parts and the current of the first parts is not limited by the current of the second parts as they are separated from each other. The different currents from the two parts may be combined or not at a box (not shown) attached to the structure to which the PV module 1200 is attached. The extending direction of the PV system 1200 is illustrated by direction X in the figure.

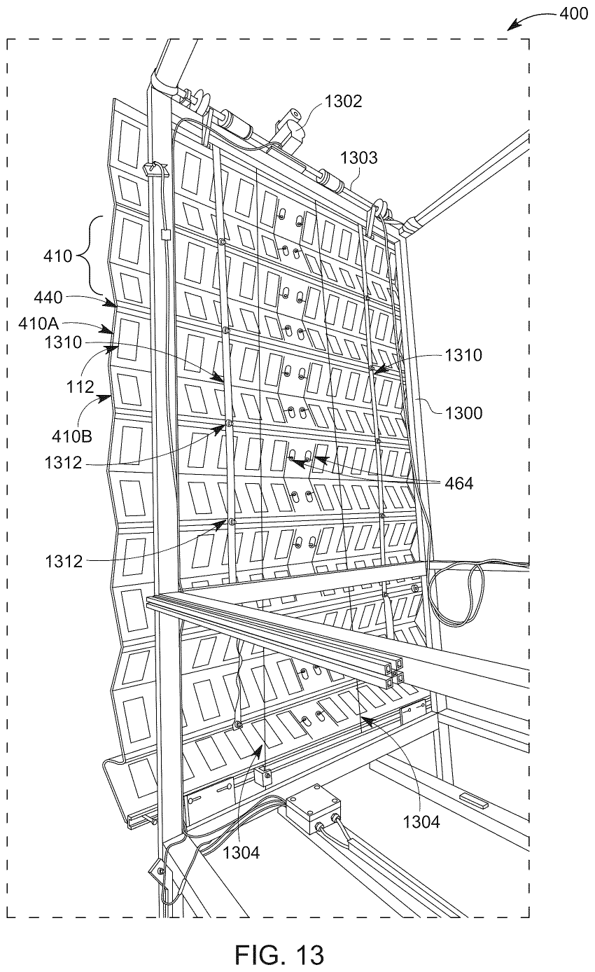

In yet another embodiment, illustrated in FIG. 13, a PV system 100/400 is vertically suspended from frame 1300. Although the figure shows the PV system 100, this embodiment also works with PV system 400. One or more motors 1302 are placed at the top of the frame 1300 for rotating a horizontal axle 1303, to fold and unfold the PV system. Mechanical cables 1304 are shown holding the modules 410. In this embodiment, assuming that the cells 112 are only distributed on the first parts 410A, not on the second parts 410B, to increase the amount of light that impinges on the cells, the first parts 410A are configured to be inclined relative to the vertical, with a desired angle. This desired angle is achieved by attaching limiters 1310 (e.g., a band) on the back of modules 410. The limiters 1310 have a length smaller than a width of the modules 410 and thus, the limiters prevent the modules 410 to fully extend, i.e., to become flat. The modules 410 remain partially folded, as shown in FIG. 13, which means that all first parts 410A are facing the sun, thus increasing the amount of light impinging on the cells 112. The length of the limiters 1310 may be manually adjusted by the operator of the PV system 100/400. The limiters may be made of fabric, metal, plastic, etc. The limiters 1310 may be added to the connecting mechanism 440 with pins 1312 (or similar means). In one application, the limiter 1310 may be adjustable, for example, may include a tri-glide slide or D-ring or slider, etc.

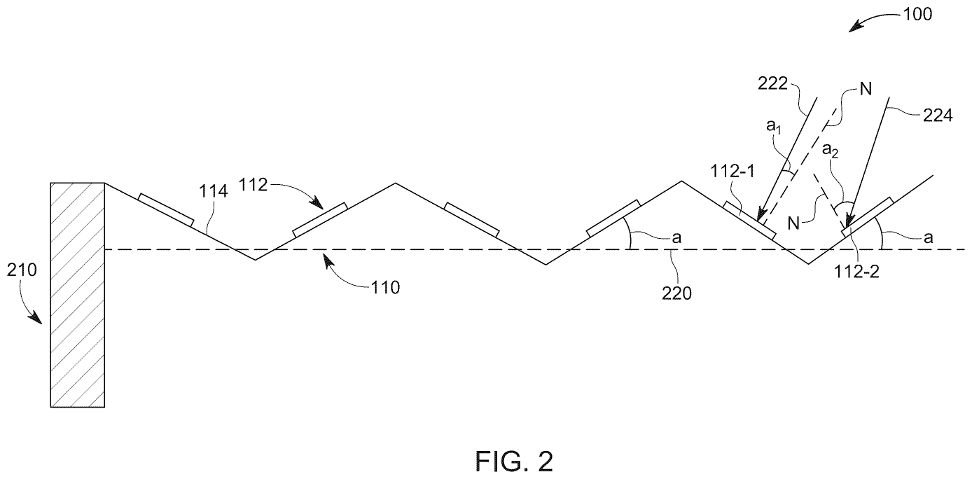

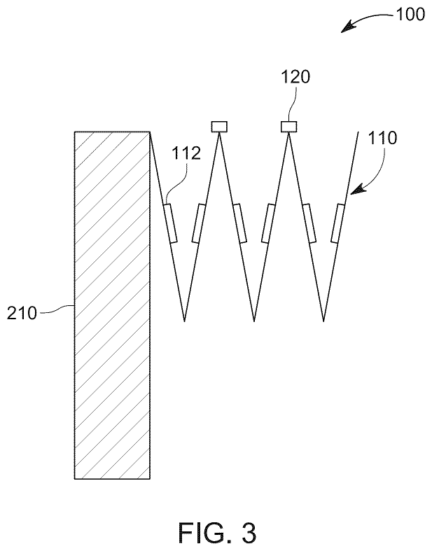

While FIGS. 2 and 3 show a horizontal installation of a PV system, and FIG. 13 shows a vertical installation of the PV system, one skilled in the art would understand that an angular configuration of the PV system is possible. The term “angular configuration” is understood in this description as meaning that the PV module, when fully extended, is neither perpendicular nor parallel to the Earth's surface, but makes an angle between 0 and 90 with the surface. This angular configuration indicate that the modules 410 could be set up at an optimal angle for solar energy generation, depending on the geographic location in the world, similar to fixed tilt installations outdoors. The angular orientation of the PV system can add several percent in total energy generation, depending on the location.

Returning to the PV system 400 of FIG. 4A, the empty side (areas 410A in FIG. 4A) of the modules 410 may be transparent, i.e., allows the sunlight to pass through, as previously discussed. In one embodiment, various materials may be used for the first parts 410A to reduce their transparency. For example, the transparency of the materials used for the first parts 410A may be selected to be between 100 and 0%. This means that the transparency of the entire module 410 becomes between 100 and 50%. A specific transparency can be achieved by coating, adhesion, selecting materials with a specific optical density, or using plural materials with different optical densities.

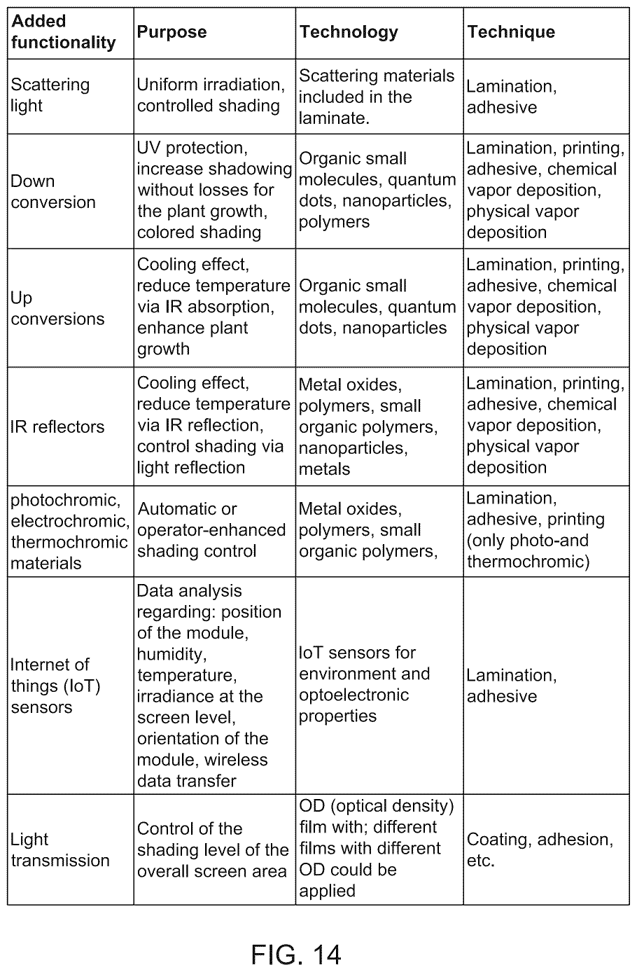

The first parts 410A of the modules 410 may also be functionalized with a material or sensor 480 as now discussed. One example of functionalization is embedding a light scattering technology that creates a uniform light irradiation after passing the modules, avoiding a shaded pattern generated by the string of cells. The scattering of light can be achieved by laminating specific materials in the empty side (first area). Similarly, the first area of each module can be empowered with highly technical optical materials and nanotechnologies to achieve unique functions. Examples of this functionalization includes: (1) embedding quantum dots, (2) spectral down converters (converting high energy light to low energy light), (3) up spectral converters (converting low energy light to high energy light), (4) translucent materials, (5) infrared (IR) reflectors, (6) photochromic, electrochromic, and thermochromic materials, (7) sensors, and/or (8) light transmission material for controlling an optical density. In one embodiment, the first parts offer the opportunity to install small sensors to monitor the environment or the functionalities at the module level. The purpose of these elements or materials are summarized in the table of FIG. 14. Examples of these sensors are often found in internet of things (IoT) applications, with self-powered beacons that can track irradiance, temperature, and position, transferring the data wirelessly to the communication center, etc. Flat IoT sensors can be included in the first parts either via lamination (i.e., within the structure of the modules) or using adhesives (i.e., being attached to the finished module). The sensors can be self-powered with an independent solar cell, or they can be connected to the module electric circuit. Data communication can be achieved via cabling, following the electrical circuit of the module, or in a wireless manner.

The terms “about” or “substantially” are used in this application to mean a variation of up to 20% of the parameter characterized by this term.

It will be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

The disclosed embodiments provide a modular asymmetric PV system that is retractable so that it can be adjusted between a fully retracted state and a fully open state to control not only an amount of electrical energy that is generated by the PV cells, but to also control an amount of solar light that passes through the PV system and/or a shadow generated by the PV system. To prevent current or voltage limitations due to cells that are less exposed to light, a part of each module of the PV system is provided with no solar cells while the other part includes all the solar cells. The electricity and light/shadow can be used to power and/or control peripheral instrumentation or processes or simply shadowing. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

The entire content of all the publications listed herein is incorporated by reference in this patent application.
[1] U.S. Pat. No. 11,711,053.
[2] International Patent Application Publication No. WO 2023/238057.
[3] U.S. Patent Application Publication No. 2024/0006547.

1. A retractable and modular photovoltaic (PV) system for transforming solar energy into electrical energy, the PV system comprising:
a first asymmetric PV module including (i) a first part free of PV cells, and (ii) a second part including first plural PV cells for generating the electrical energy;
a first end junction box electrically connected to a first end of the first plural PV cells; and
a second end junction box electrically connected to a second end of the first plural PV cells,
wherein the first asymmetric PV module is made of a bendable material so that the first part bends relative to the second part along a boundary when the first asymmetric PV module is retracted.

2. The PV system of claim 1, wherein a surface area of the first part is substantially equal to a surface area of the second part.

3. The PV system of claim 1, wherein the first part of the first asymmetric PV module includes at least one of a scattering light material, a down conversion material, an up conversion material, an infrared reflector, a sensor, a light transmission material, or a shading control device.

4. The PV system of claim 1, further comprising:
a second PV module having a first part free of PV cells and a second part including second plural PV cells.

5. The PV system of claim 4, wherein the first and second end junctions box electrically sandwich both the first and second plural PV cells.

6. The PV system of claim 4, wherein each of the first and second asymmetric PV modules has all the PV cells electrically sandwiched between corresponding junction boxes.

7. The PV system of claim 4, wherein each of the first and second asymmetric PV modules has sub-groups of PV cells electrically sandwiched between corresponding junction boxes.

8. The PV system of claim 4, wherein the first and second asymmetric PV modules are electrically connected to each other with an electrical cable, and the electrical cable is fixed by a first clamp attached to the second part of the first asymmetric PV module, and the electrical cable is guided by a second clamp attached to the first part of the first asymmetric PV module.

9. The PV system of claim 8, wherein the first clamp has an internal diameter smaller than the second clamp.

10. The PV system of claim 4, further comprising:
plural junction boxes, in addition to the first and second end junction boxes, the plural junction boxes being configured to separate the first and second plural PV cells into sub-groups.

11. The PV system of claim 10, further comprising:
plural bypass diodes associated in a one to one relationship to junction boxes of the plural junction boxes that are located on the first asymmetric PV module but not the second asymmetric PV module.

12. The PV system of claim 11, wherein the plural bypass diodes are configured to prevent a current flow through one or more sub-groups when a negative voltage is generated by the one or more sub-groups.

13. The PV system of claim 10, wherein pairs of junction boxes of the plural junction boxes are electrically connected through a direct cable to bypass a corresponding sub-group.

14. The PV system of claim 1, further comprising:
a connecting mechanism configured to connect the first asymmetric PV module to a second asymmetric PV module; and
a limiter device attached between the connection mechanism and an adjacent connection mechanism to achieve an angle that generates maximum power.

15. A retractable and modular photovoltaic (PV) system for transforming solar energy into electrical energy, the PV system comprising:
plural asymmetric PV modules each including (i) a first part free of PV cells, and (ii) a second part including plural PV cells for generating the electrical energy;
a first end junction box electrically connected to a first end of a string of all plural PV cells; and
a second end junction box electrically connected to a second end of the string of all the first plural PV cells,
wherein each asymmetric PV module is made of a bendable material so that the first part bends relative to the second part along a boundary when the plural asymmetric PV modules are retracted.

16. The PV system of claim 15, wherein the first part of each of the asymmetric PV modules includes at least one of a scattering light material, a down conversion material, an up conversion material, an infrared reflector, a sensor, a light transmission material, or a shading control device.

17. The PV system of claim 15, wherein each of the asymmetric PV modules has sub-groups of PV cells electrically sandwiched between corresponding junction boxes.

18. The PV system of claim 17, wherein adjacent asymmetric PV modules are electrically connected to each other with a corresponding electrical cable, and the electrical cable is fixed by a first clamp attached to the second part of one of the adjacent asymmetric PV modules and the electrical cable is guided by a second clamp attached to the second part of the one of the asymmetric PV modules.

19. The PV system of claim 15, further comprising:
plural junction boxes in addition to the first and second end junction boxes, the plural junction boxes being configured to separate the plural PV cells into sub-groups for each PV module; and
plural bypass diodes associated in a one to one relationship to junction boxes of the plural junction boxes that are located on the first asymmetric PV module but not the second asymmetric PV module,
wherein the plural bypass diodes are configured to prevent a current flow through one or more sub-groups when a negative voltage is generated by the one or more sub-groups.

20. The PV system of claim 15, further comprising:
plural connecting mechanisms configured to connect additional asymmetric PV modules; and
a limiter device attached between the connection mechanisms to achieve an angle that generates maximum power.
